(19) United States
(12) Patent Application Publication
(10) Pub. No.: US 2022/0293657 A1
(43) Pub. Date: Sep. 15, 2022

(54) INTEGRATED OPTICAL SENSOR AND METHOD OF MANUFACTURING THE SAME

(71) Applicant: EGIS TECHNOLOGY INC., Hsinchu City (TW)

(72) Inventors: Bruce C. S. CHOU, Taipei City (TW); Chen-Chih FAN, Taipei City (TW)

(21) Appl. No.: 17/761,880

(22) PCT Filed: Mar. 18, 2020
(86) PCT No.: PCT/CN2020/079865

§ 371 Date: Mar. 18, 2022

Related U.S. Application Data
(60) Provisional application No. 62/903,949, filed on Sep. 23, 2019.
(60) Provisional application No. 62/926,713, filed on Oct. 28, 2019.
(60) Provisional application No. 62/941,933, filed on Nov. 29, 2019.
(60) Provisional application No. 62/941,935, filed on Nov. 29, 2019.

(51) Int. Cl. H01L 27/146; G02B 5/00

(52) U.S. Cl. CPC H01L 27/14623; G02B 5/003; G02B 5/008; H01L 27/14627; H01L 27/14685; G06V 40/1318

(57) ABSTRACT

An integrated optical sensor includes a substrate, an optical module layer and micro lenses. The substrate has sensing pixels. The optical module layer is disposed on the substrate. The micro lenses are disposed on the optical module layer. A thickness of the optical module layer defines a focal length of the micro lenses, and the sensing pixels sense object light of an object, which is focused by the micro lenses and optically processed by the optical module layer. The optical module layer includes a metal light shielding layer and an inter-metal dielectric layer disposed above the metal light shielding layer. The object light reaches the sensing pixels through apertures of the metal light shielding layer. A method of manufacturing the integrated optical sensor is also provided.

### CROSS-REFERENCE TO RELATED APPLICATIONS

This application claims priorities of U.S. Provisional Patent Application Ser. No. 62/903,949, entitled “Fingerprint Sensor” and filed on Sep. 23, 2019; U.S. Provisional Patent Application Ser. No. 62/926,713, entitled “Fingerprint Sensor” and filed on Oct. 28, 2019; U.S. Provisional Patent Application Ser. No. 62/941,935, entitled “Fingerprint Sensor” and filed on Nov. 29, 2019; and U.S. Provisional Patent Application Ser. No. 62/941,933, entitled “Fingerprint Sensor Implemented On TFT” and filed on Nov. 29, 2019 under 35 U.S.C. § 119, the entire contents of which are hereby incorporated by reference.

### BACKGROUND OF THE INVENTION

### Field of the Invention

This disclosure relates to an integrated optical sensor and a method of manufacturing the same, and more particularly to an integrated optical sensor capable of being manufacturing by an integrated semiconductor process, and a method of manufacturing the same, wherein a filter structure layer is composed of materials compatible with a complementary metal-oxide semiconductor (CMOS) process, so that the filter structure layer can be integrated into the CMOS process.

### Description of the Related Art

Today's mobile electronic devices (e.g., mobile phones, tablet computers, notebook computers and the like) are usually equipped with user biometrics recognition systems including different techniques relating to, for example, fingerprint, face, iris and the like, to protect security of personal data. Portable devices applied to mobile phones, smart watches and the like also have the mobile payment function, which further becomes a standard function for the user's biometrics recognition. The portable device, such as the mobile phone and the like, is further developed toward the full-display (or super-narrow border) trend, so that conventional capacitive fingerprint buttons, such as those of iphone 5 to iphone 8, can no longer be used, and new minimized optical imaging devices, some of which are very similar to the conventional camera module having CMOS image sensor (referred to as CIS) sensing members and an optical lens module, are thus evolved. The minimized optical imaging device is disposed under the display as an under-display device. The image of the object (more particularly the fingerprint) placed above the display can be captured through the partial light-permeable display (more particularly the organic light emitting diode (OLED) display), and this can be called as fingerprint on display (FOD).

The prior art optical sensor has a filter layer and a lens, which are formed by a package process and cannot be integrated in a semiconductor process of forming a sensing chip including sensing pixels. Thus, the optical sensor cannot be manufactured in an integrated manner. Therefore, the manufacturing process of the overall optical sensor is complicated, and the optical sensor has the poor precision and the high cost.

### BRIEF SUMMARY OF THE INVENTION

It is therefore an objective of this disclosure to provide an integrated optical sensor and a method of manufacturing the same, wherein dielectric layers and metal layers used in the semiconductor process function as a collimator to provide a focal length for micro lenses, apertures, micro lenses and a filter structure layer without the need of polymeric materials frequently used in a post process to manufacture a transparent layer and a light shielding layer.

To achieve the above-identified objective, this disclosure provides an integrated optical sensor including a substrate, an optical module layer and multiple micro lenses. The substrate has multiple sensing pixels. The optical module layer is disposed on the substrate. The micro lenses are disposed on the optical module layer. A thickness of the optical module layer defines a focal length of the micro lenses. The sensing pixels sense object light of an object, which is focused by the micro lenses and optically processed by the optical module layer. The optical module layer includes a filter structure layer for filtering the object light. The optical module layer is constituted by materials compatible with a CMOS process, so that the filter structure layer can be integrated in the CMOS process.

This disclosure also provides a method of manufacturing an integrated optical sensor. The method includes steps of: using a semiconductor process to form multiple sensing pixels on a substrate; forming an optical module layer on the substrate and the sensing pixels in the process; and forming multiple micro lenses on the optical module layer in the process.

This disclosure also provides an integrated optical sensor including: a substrate having multiple sensing pixels; an optical module layer disposed on the substrate; and multiple micro lenses disposed on the optical module layer, wherein a thickness of the optical module layer defines a focal length of the micro lenses; the sensing pixels sense object light of an object, which is focused by the micro lenses and optically processed by the optical module layer, wherein the optical module layer includes a first metal light shielding layer and a first inter-metal dielectric layer disposed above the first metal light shielding layer, and the object light reaches the sensing pixels through multiple first apertures of the first metal light shielding layer.

This disclosure further provides a method of manufacturing an integrated optical sensor. The method includes steps of: using a semiconductor process to form multiple sensing pixels on a substrate; forming an optical module layer on the substrate and the sensing pixels in the semiconductor process; and forming multiple micro lenses on the optical module layer in the semiconductor process, wherein a thickness of the optical module layer defines a focal length of the micro lenses, the sensing pixels sense object light of an object, which is focused by the micro lenses and optically processed by the optical module layer. the optical module layer includes a first metal light shielding layer and a first inter-metal dielectric layer disposed above the first metal light shielding layer, and the object light reaches the sensing pixels through multiple first apertures of the first metal light shielding layer.

With the above-mentioned integrated optical sensor, the sensing pixels, the optical module layer and the micro lenses can be formed while active or passive devices are formed in the semiconductor process, and bonding pads and electrical connection structures of interconnection wires may also be formed at the same time. Using the optical module layer to precisely control the imaging focal length of the micro lenses can achieve the effects of enhancing the process precision and decreasing the manufacturing cost. In addition, the optical sensor is applicable to both a semiconductor sensor and a thin-film transistor (TFT) sensor.

In order to make the above-mentioned content of this disclosure more obvious and be easily understood, preferred embodiments will be described in detail as follows in conjunction with the accompanying drawings.

### BRIEF DESCRIPTION OF THE SEVERAL VIEWS OF THE DRAWINGS

FIGS. 1A to 1C are schematically partial cross-sectional views showing several examples of an integrated optical sensor according to a preferred embodiment of this disclosure.

FIGS. 2 to 6 are schematic views showing modified examples of FIG. 1C.

FIGS. 7 to 11 are schematic views showing modified examples of FIG. 1C.

FIG. 12 is a schematic view showing fingerprint image capturing and processing.

FIG. 13 is a schematic view showing a configuration of tilt directions of the oblique light of FIG. 11.

FIG. 14 is a comparison diagram showing the area of the fingerprint image captured by the integrated optical sensor of FIG. 12.

FIG. 15 is a schematic view showing another configuration of tilt directions of the oblique light of FIG. 11.

FIG. 16 is a comparison diagram showing the area of the fingerprint image captured by the integrated optical sensor of FIG. 15.

FIGS. 17 to 21 are schematic views showing modified examples of FIG. 1C.

FIGS. 22 to 26 are schematic views showing modified examples of FIG. 18.

### SYMBOL

A1: area
A2: distribution area
AR1: interference region
D1, D2, D3, D4: tilt direction
F: object
IM1 to IM5: image
OA1, OA2: central optical axis
TL: object light
TL1: normal light
TL2: oblique light
TL3: oblique light
10: substrate
11: sensing pixel
15: TFT sensor
20: optical module layer
21: lower dielectric module layer
22: first metal light shielding layer
22A: first aperture
23: first inter-metal dielectric layer
23′: support substrate
24: filter structure layer
25: second inter-metal dielectric layer
25′: spacer layer
26: second metal light shielding layer
26A: second aperture
27: upper dielectric module layer
31: anti-reflective layer
40: micro lens
50: wiring layer set
52: first metal layer
53: lower dielectric layer
54: second metal layer
56: third metal layer
58: lower interconnection wire
60: light receiving module
100: optical sensor

### DETAILED DESCRIPTION OF THE INVENTION

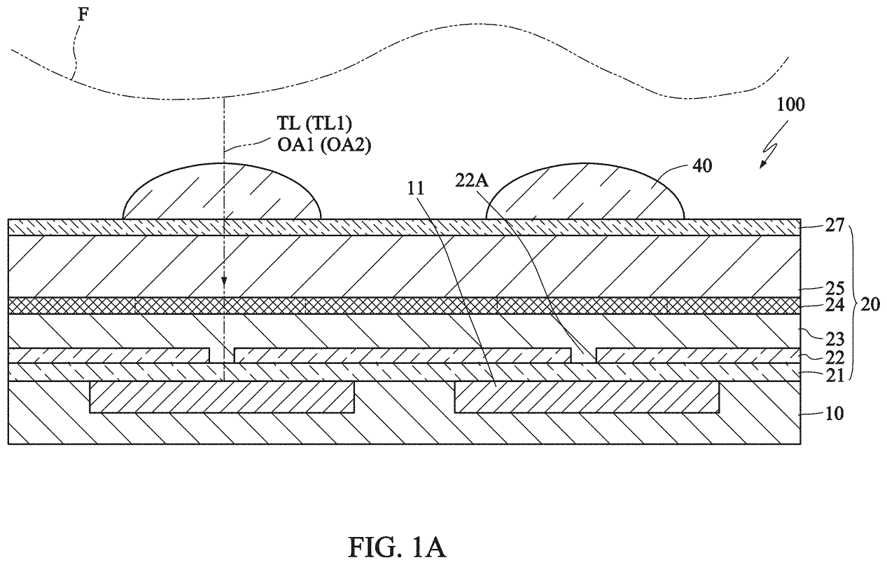

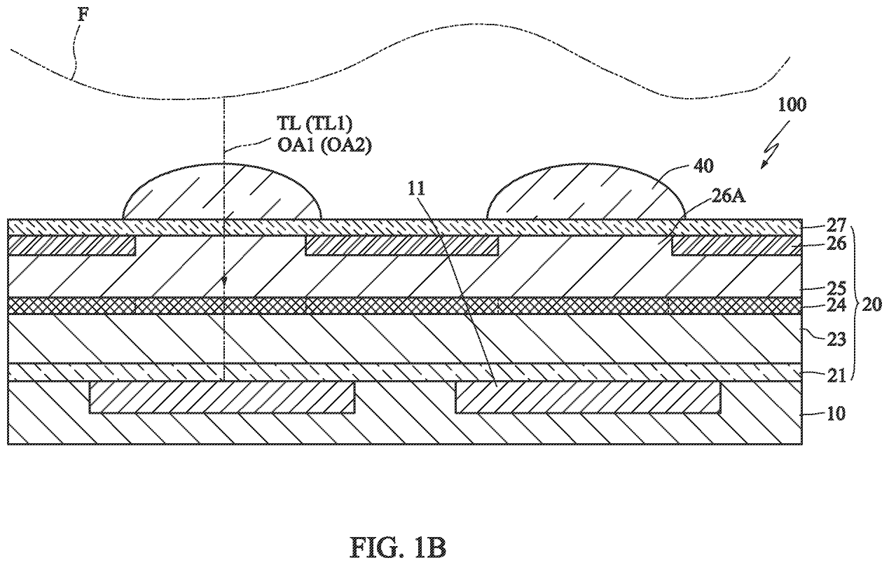

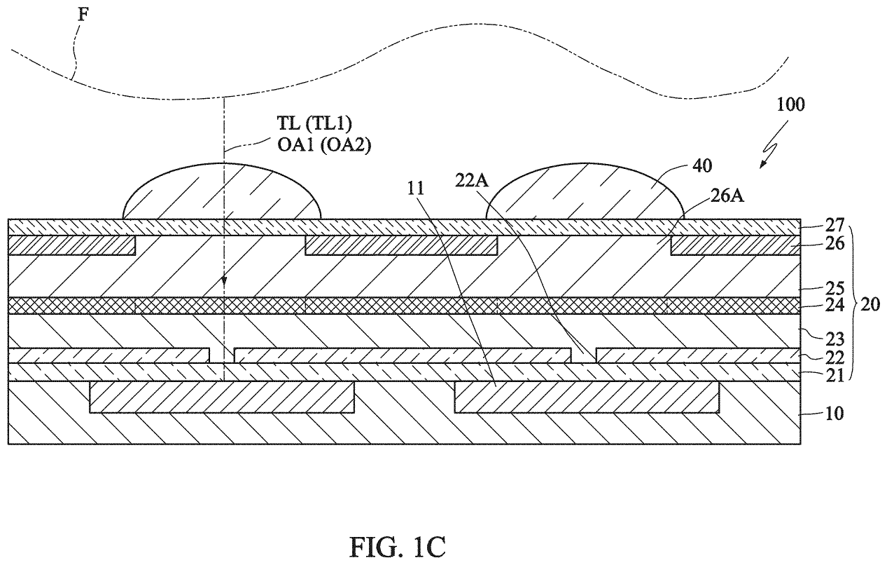

FIGS. 1A to 1C are schematically partial cross-sectional views showing several examples of an integrated optical sensor 100 according to a preferred embodiment of this disclosure. Referring to FIG. 1A, the integrated optical sensor 100 includes a substrate 10 (e.g., a semiconductor substrate, such as a silicon substrate), an optical module layer 20 and multiple micro lenses 40. The substrate 10 has multiple sensing pixels 11. The optical module layer 20 is disposed on the substrate 10. The micro lenses 40 are disposed on the optical module layer 20. A thickness of the optical module layer 20 defines a focal length or focal lengths of the micro lenses 40. The sensing pixels 11 sense object light TL of an object F, which is focused by the micro lenses 40 and optically processed (collimated in one example) by the optical module layer 20. The optical module layer 20 includes a filter structure layer 24, which may be at least one metal layer or at least one additional metal layer or non-metallic layer in a CMOS process, and filters the object light TL. The optical module layer 20 is composed of a material or materials compatible with the CMOS process, so that the filter structure layer 24 can be integrated into the CMOS process (e.g., the front process). The above-mentioned characteristics can achieve the useful effect of this disclosure. That is, the integrated optical sensor can be completed in the CMOS process. In addition, the optical module layer 20 may further include a first metal light shielding layer 22, which may be a standard metal layer, or an additional metal layer or non-metallic layer in the CMOS process, and a first inter-metal dielectric layer 23 disposed above the first metal light shielding layer 22 and under the filter structure layer 24. The object light TL reaches the sensing pixels 11 sequentially through the filter structure layer 24 and multiple first apertures 22A of the first metal light shielding layer 22. It is worth noting that the first inter-metal dielectric layer 23 is disposed between the first metal light shielding layer 22 and the filter structure layer 24, and the object light TL reaches the sensing pixels 11 through the filter structure layer 24 and the first apertures 22A. In this embodiment, the substrate 10, the micro lenses 40 and the optical module layer 20 are constituted by materials compatible with the CMOS process.

Referring to FIG. 1B, this example is similar to FIG. 1A except for the difference that the optical module layer 20 has no first metal light shielding layer 22, but still includes a second metal light shielding layer 26, which may be a standard metal layer, or an additional metal layer or non-metallic layer in the CMOS process, and a second inter-metal dielectric layer 25 disposed under the second metal light shielding layer 26 and above the filter structure layer 24. The object light TL reaches the sensing pixels 11 sequentially through multiple second apertures 26A of the second metal light shielding layer 26 and the filter structure layer 24. In one example, the filter structure of the filter structure layer 24 is a filter grating. Based on the optical path of the object light TL, it is possible to configure the filter structure in only regions of the filter structure layer 24, which substantially correspond to the second apertures 26A, and other regions are still configured with the light shielding structure.

Referring to FIG. 1C, this example is similar to FIGS. 1A and 1B except for the difference that this example is integrated with the first metal light shielding layer 22 and the second metal light shielding layer 26 to achieve the multi-angle stray light shielding effect.

The manufacturing processes of semiconductor integrated circuits can be substantially classified into front processes and post processes. In the front processes, devices, including resistors, capacitors, diodes, transistors and the like, and interconnections for inter-connecting these devices together are formed on a silicon wafer. The post processes include a package process and a test process. The front processes include: film formation processes for forming insulating layers, conductor layers and semiconductor layers; coating a photoresist film or photosensitive resin on a surface of a film and pattering the photoresist film by way of lithographing; and etching processes of selectively removing base material films with the photoresist patterns serving as masks.

The method of manufacturing the integrated optical sensor includes the following steps. First, a semiconductor process (e.g., front process) is adopted to form multiple sensing pixels 11 on a substrate 10. Then, an optical module layer 20 is formed on the substrate 10 and the sensing pixels 11 in the semiconductor process. Next, multiple micro lenses 40 are formed on the optical module layer 20 in the semiconductor process. The micro lenses 40 are formed using a silicon dioxide material or a polymeric material in conjunction with a grayscale mask and etching.

With the above-mentioned structure and manufacturing method, the image sensing function of the integrated optical sensor 100 of sensing biometrics characteristics, including a fingerprint image, a vein image, a blood oxygen concentration image and the like, can be obtained, and the effects of enhancing the process precision and decreasing the manufacturing cost can be achieved.

In the integrated optical sensor 100, the second metal light shielding layer 26 is disposed above the filter structure layer 24, and has multiple second apertures 26A through which the object light TL passes. The second inter-metal dielectric layer 25 is disposed between the filter structure layer 24 and the second metal light shielding layer 26. It is worth noting that the first metal light shielding layer 22, the filter structure layer 24 and/or the second metal light shielding layer 26 may be a metal layer, a non-metallic layer or a composite layer including metallic and non-metallic materials.

The optical module layer 20 may further include: a lower dielectric module layer 21, which may include partial or entire parts of inter-layer dielectric (ILD) layers, inter-metal dielectric (BID) layers and metal layers formed in the CMOS process (more particularly the front process); a second metal light shielding layer 26; a second inter-metal dielectric layer 25; and an upper dielectric module layer 27. The lower dielectric module layer 21 is disposed on the sensing pixels 11. The first metal light shielding layer 22 is disposed on the lower dielectric module layer 21, and the filter structure layer 24 is disposed above the first metal light shielding layer 22. The second metal light shielding layer 26 is disposed above the filter structure layer 24, and has multiple second apertures 26A through which the object light TL passes. The second inter-metal dielectric layer 25 is disposed between the filter structure layer 24 and the second metal light shielding layer 26. The micro lenses 40 are disposed on the upper dielectric module layer 27, which is disposed on the second metal light shielding layer 26.

In one example, the upper dielectric module layer 27 is a transparent layer for protecting the second metal light shielding layer 26. In another example, the upper dielectric module layer 27 is a filter layer made of a high refractive material having a high refractivity, wherein the material having the higher refractivity has the higher refracting ability for the incident light, and effectively makes the object light TL reach the sensing pixels 11. The dielectric module layer itself may be a single material layer or a combination of multiple layers of materials, and may include, for example, an upper planarized dielectric layer (e.g., silicon oxide, silicon nitride or a combination thereof) and a buffer layer for manufacturing the micro lenses in the CMOS process.

Because the semiconductor process is adopted to form the optical module layer 20, the first metal light shielding layer 22, the filter structure layer 24 and the first inter-metal dielectric layer 23 are constituted by semiconductor-process compatible materials. In addition, because the metal layer may function as the electrical connection medium, a certain metal layer may be adopted to form one or multiple bonding pads, so that the first metal light shielding layer 22 and the filter structure layer 24 are electrically connected to the sensing pixels 11 and the one or multiple bonding pads of the integrated optical sensor 100.

Therefore, the main essence of this disclosure is to adopt the dielectric layer(s) and metal layer(s) of the semiconductor process as a collimator for providing the required focal length of the micro lenses, the apertures, the micro lenses and the filter structure layer without the need of polymeric materials frequently used in the post process to manufacture a transparent layer and a light shielding layer. So, the processes of integrating the sensing chip with the collimator can be achieved.

In the semiconductor process, a first metal layer (may also be a second metal layer or other metal layers) is adopted to form the apertures, the ILD or BID is adopted to form the focal length of the micro lenses; and the metal layer (may be an arbitrary metal layer) is adopted to form the grating configuration or the high-refractivity material layer, or a dielectric material configuration (e.g., diffraction optical element (DOE)) or another optical configuration is adopted to form the infrared (IR) filter structure layer. The micro lenses may be formed using the silicon dioxide (SiO₂) or polymeric material in conjunction with a grayscale mask and etching, or using other semiconductor compatible materials.

In the integrated optical sensor 100 of FIG. 1C, the central optical axes OA1 of the first apertures 22A are respectively aligned with the central optical axes OA2 of the micro lenses 40, and the first apertures 22A correspond to the micro lenses 40 and the sensing pixels 11 in a one-to-one manner, so that the sensing pixels 11 sense normal light TL1 of the object light TL, which is focused by the micro lenses 40. respectively through the first apertures 22A. The normal light TL1 is substantially perpendicular to the central optical axes OA1 and OA2, wherein angles between the normal light TL1 and the central optical axes OA1 and OA2 range between ±45 and 0 degrees, and preferably range between ±30 and 0 degrees, range between ±15 and 0 degrees, range between ±10 and 0 degrees or range between ±5 and 0 degrees.

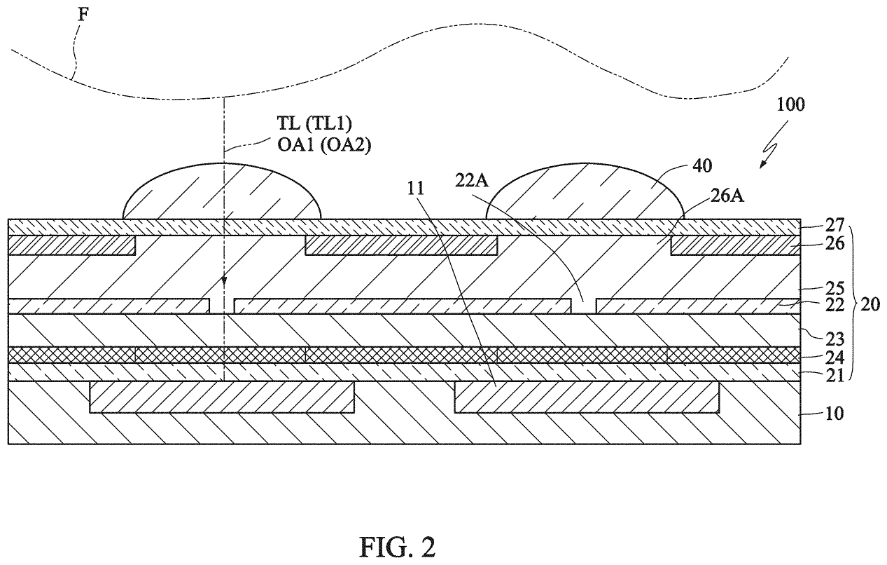

FIGS. 2 to 6 are schematic views showing modified examples of FIG. 1C. Referring to FIG. 2, this example is similar to FIG. 1C except for the difference that the first metal light shielding layer 22 and the filter structure layer 24 of FIG. 2 have interchanged positions. That is, the first metal light shielding layer 22 is disposed above the filter structure layer 24. Therefore, in the optical module layer 20, the lower dielectric module layer 21 is disposed on the sensing pixels 11; the filter structure layer 24 is disposed on the lower dielectric module layer 21; the first metal light shielding layer 22 is disposed above the filter structure layer 24; the second metal light shielding layer 26 is disposed above the filter structure layer 24, and has multiple second apertures 26A through which the object light TL passes; the second inter-metal dielectric layer 25 is disposed between the first metal light shielding layer 22 and the second metal light shielding layer 26; and the upper dielectric module layer 27 is disposed on the second metal light shielding layer 26.

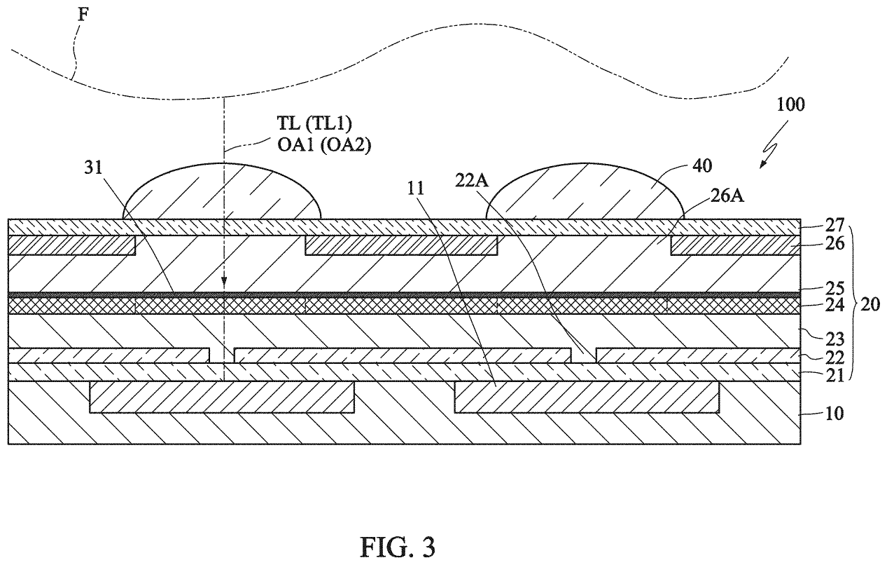

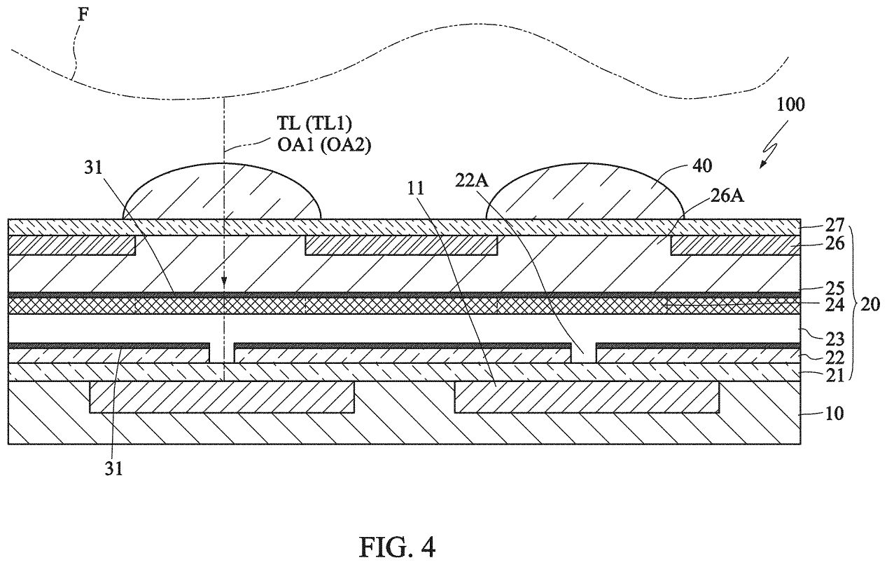

Referring to FIGS. 3 and 4, in order to prevent the noise from being caused by the stray light generated when the light is reflected between the metal layers, layers made of materials, such as carbon, titanium nitride (TiN) or other semiconductor compatible materials capable of reducing the reflection of the metal material, may be added between the metal lavers to absorb the reflected stray light, and this anti-reflective layer may have one single layer or multiple layers. Therefore, the optical module layer 20 may further include an anti-reflective layer 31, which is disposed on one or both of the filter structure layer 24 and the first metal light shielding layer 22 and absorbs the reflected stray light.

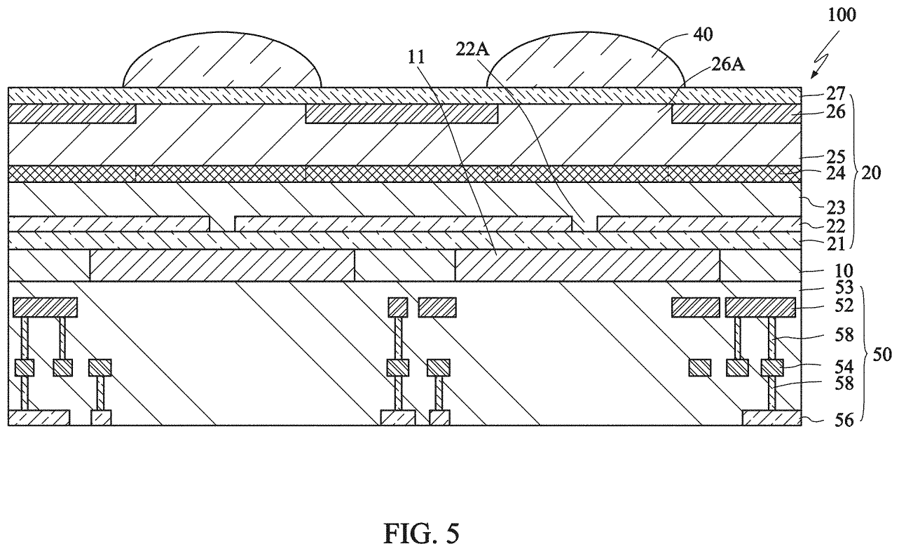

Referring to FIG. 5, the embodiment of this disclosure provides a back-side illumination (BSI) configuration, and the semiconductor process may further be added with other processes to form an integrated collimator structure. In this case, the optical sensor 100 further includes a wiring layer set 50, and the substrate 10 is disposed on the wiring layer set 50. The wiring layer set 50 is electrically connected to the sensing pixels 11. Specifically, the wiring layer set 50 includes a third metal layer 56, a second metal layer 54, a first metal layer 52, a lower dielectric layer 53 and multiple lower interconnection wires 58. The second metal layer 54 is disposed above the third metal layer 56. The first metal layer 52 is disposed above the second metal layer 54. The lower dielectric layer 53 and the lower interconnection wires 58 are disposed between the first metal layer 52, the second metal layer 54, the third metal layer 56 and the substrate 10. The lower interconnection wires 58 are electrically connected to the first metal layer 52, the second metal layer 54 and the third metal layer 56. The lower interconnection wires 58 may also be electrically connected to the sensing pixels 11. Upon actual manufacturing, the lower dielectric module layer 21, the substrate 10 and the wiring layer set 50 are firstly formed on a wafer, and the optical module layer 20 (without the lower dielectric module layer 21) and the micro lenses 40 are formed on the other wafer. Then, the two wafers are bonded together to form the structure of FIG. 5.

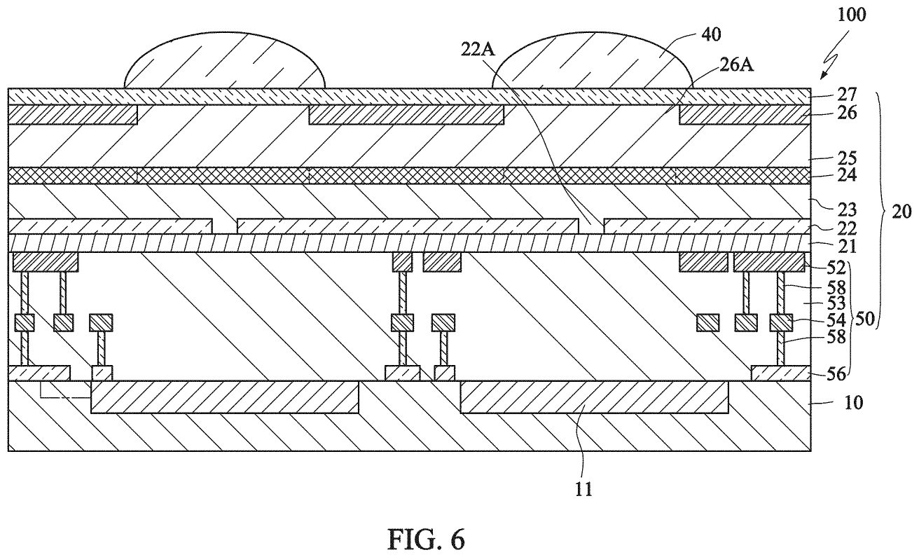

Referring to FIG. 6, the embodiment of this disclosure provides a front-side illumination (FSI) configuration, and the semiconductor process may further be added with other processes to form an integrated collimator structure. In this case, the optical module layer 20 further includes a wiring layer set 50, which is disposed on the substrate 10, may also be referred to as a transparent dielectric layer, and may also be electrically connected to the sensing pixels 11. The wiring layer set 50 includes a third metal layer 56, a second metal layer 54, a first metal layer 52, a lower dielectric layer 53 and multiple lower interconnection wires 58. The third metal layer 56 is disposed on the substrate 10. The second metal layer 54 is disposed above the third metal layer 56. The first metal layer 52 is disposed above the second metal layer 54, and the first metal light shielding layer 22 is disposed above the first metal layer 52. The lower dielectric layer 53 and the lower interconnection wires 58 are disposed between the first metal layer 52, the second metal layer 54, the third metal layer 56 and the substrate 10. The lower interconnection wires 58 are electrically connected to the first metal layer 52, the second metal layer 54 and the third metal layer 56. The lower interconnection wires 58 may be electrically connected to the sensing pixels 11, wherein the first metal light shielding layer 22 is disposed above the first metal layer 52 through the lower dielectric module layer 21. Upon actual manufacturing, the lower dielectric module layer 21, the wiring layer set 50 and the substrate 10 are firstly formed on a wafer, and the optical module layer 20 (without the lower dielectric module layer 21) and the micro lenses 40 are formed on the other wafer. Then, the two wafers are bonded together to form the structure of FIG. 6.

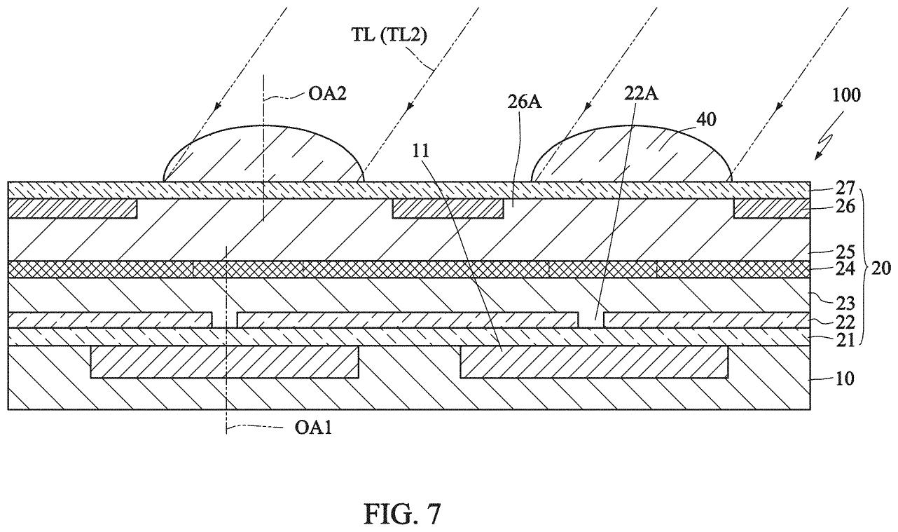

FIGS. 7 to 11 are schematic views showing modified examples of FIG. 1C. Referring to FIG. 7, the optical axes are in a mis-alignment state. That is, the central optical axes OA1 of the first apertures 22A are respectively mis-aligned with the central optical axes OA2 of the micro lenses 40 in a one-to-one manner, and the first apertures 22A correspond to the micro lenses 40 and the sensing pixels 11 in a one-to-one manner, so that the sensing pixels 11 sense oblique light TL2 of the object light TL, which is focused by the micro lenses 40, respectively through the first apertures 22A.

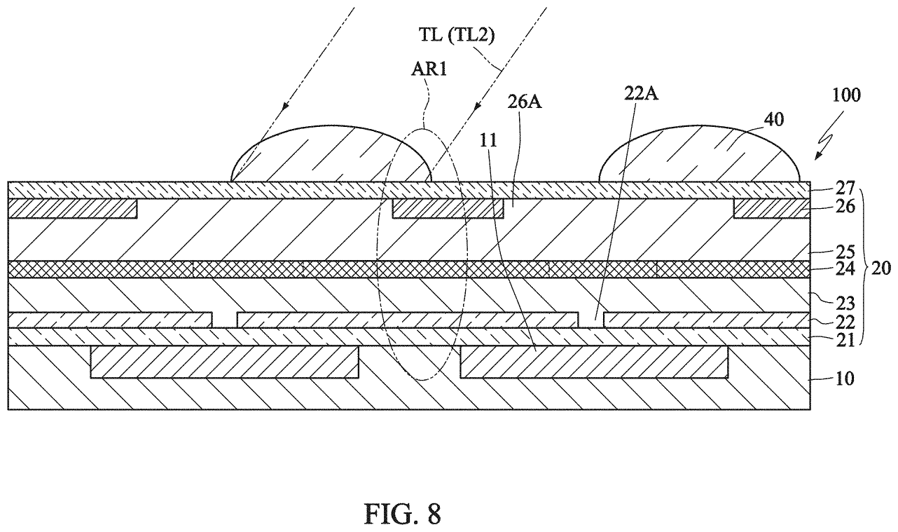

Referring to FIG. 8, if some product applications may need to control the large angle of light, the micro lens needs to have the larger offset. In this case, the circuit between the adjacent sensing pixels 11 causes the light interference. For example, in an interference region AR1, the light may interfere with the oblique light TL2.

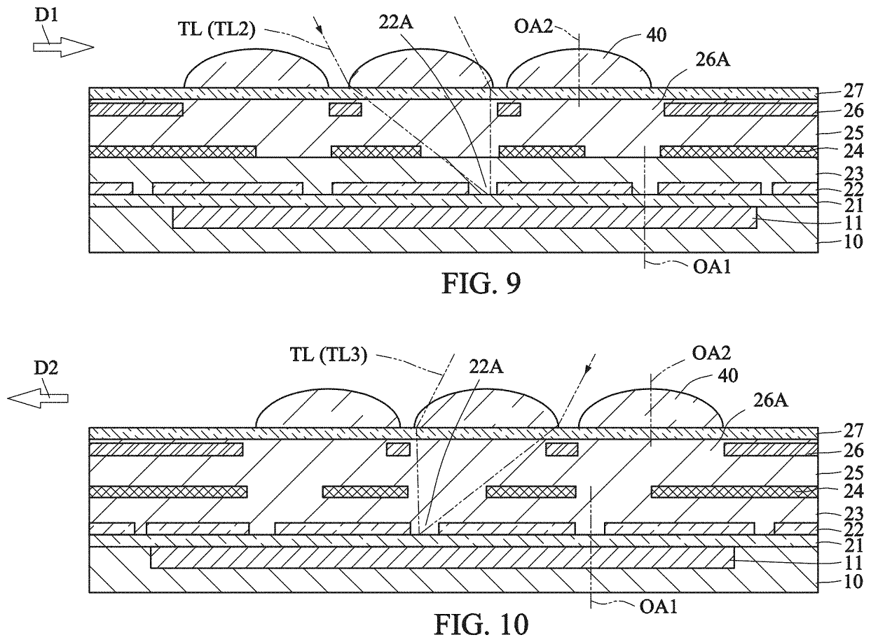

In order to solve the above-mentioned problems, FIGS. 9 and 10 provide another sensing structure, in which a many-to-one corresponding relationship of designing the offsets of the micro lenses in multiple directions is adopted to prevent the light interference from being caused by the circuit between the pixels, wherein the sensing pixels 11 correspond to the micro lenses 40 in a one-to-manner. That is, one of the sensing pixels 11 corresponds to multiple ones of the micro lenses 40 and receives the light focused by the corresponding micro lenses 40, wherein the light is the oblique light TL2 described as an example, and may also be the normal light TL1 of FIG. 1C. The micro lenses 40 correspond to the first apertures 22A in a one-to-one manner, and the central optical axes OA1 of the first apertures 22A and the central optical axes OA2 of the micro lenses 40 are respectively in the mis-alignment states.

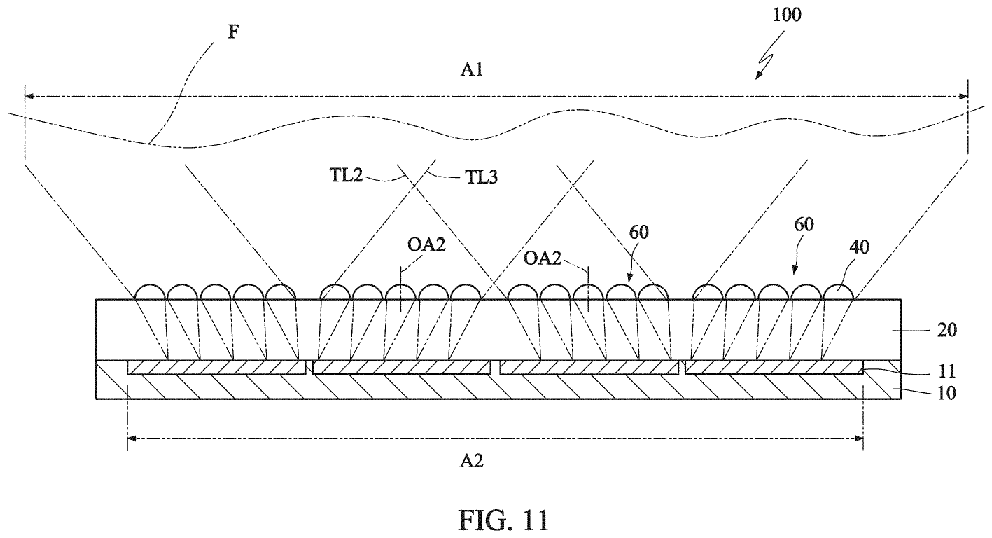

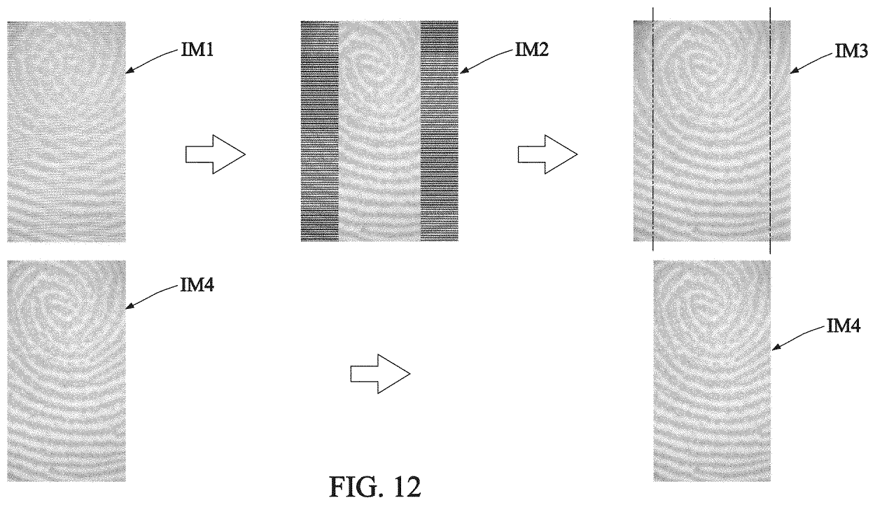

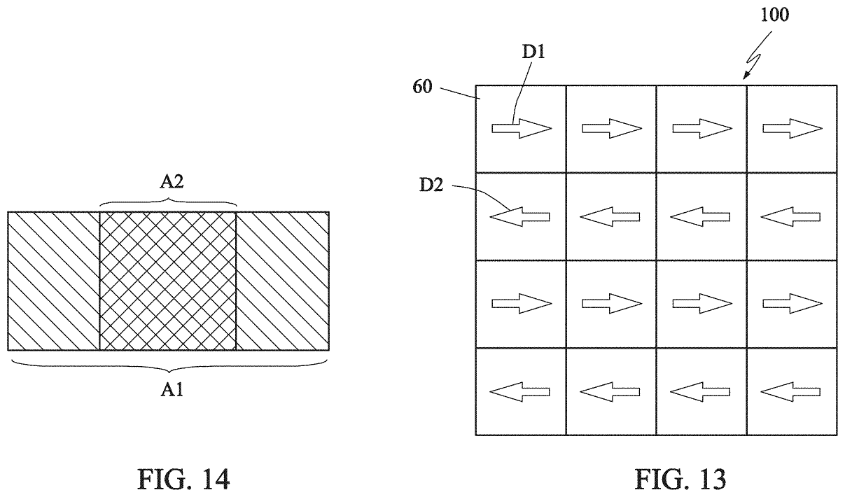

FIG. 12 is a schematic view showing fingerprint image capturing and processing. FIG. 13 is a schematic view showing a configuration of tilt directions of the oblique light of FIG. 11. FIG. 14 is a comparison diagram showing the area of the fingerprint image captured by the integrated optical sensor of FIG. 12. Referring to FIGS. 11 to 14, a fan-out collimator structure is provided, wherein the configuration of the oblique light collimator is adopted such that the direction of the oblique light received by the odd-numbered columns or rows of sensing pixels is opposite to the direction of the oblique light received by the even-numbered columns or rows of sensing pixels 11, and the fingerprint sensing area can be enlarged. That is, the optical axes of the adjacent sensing pixels 11 have opposite offset directions. In this case, the integrated optical sensor 100 has light receiving modules 60 each being constituted by one sensing pixel 11, and the micro lenses 40 and the first apertures 22A corresponding to the sensing pixel 11. The adjacent light receiving modules 60 receive the oblique light TL2 and oblique light TL3 have different tilt directions D1 and D2 with respect to the central optical axes OA2 of the micro lenses 40. On the other hand, the area A1 of the image obtained by the light receiving modules 60 sensing the object F is larger than the distribution area. A2 of the sensing pixels 11. In addition, the same row of light receiving modules 60 receive the oblique light TL2 having the same tilt direction D1/D2 with respect to the central optical axes OA2 of the micro lenses 40, and different rows of light receiving modules 60 receive the oblique light TL2 and the oblique light TL3 having different tilt directions D1 and D2 with respect to the central optical axes OA2 of the micro lenses 40. The above-mentioned configuration is the single-axis fan-out configuration. It is worth noting that the configurations of the tilt directions D1 and D2 of FIGS. 11 and 13 are provided only for the illustrative purpose. In one optical sensor 100, the light receiving modules 60 capable of receiving the normal light and the oblique light can be provided concurrently. For example, the middle light receiving module 60 receives the normal light, and the light receiving modules 60 on peripheral sides or two sides receive different directions of oblique light.

In FIG. 12, the fan-out optical sensor senses an image IM1, which is processed into an image IM2 by a fan-out image signal processing method, wherein the image IM2 is processed into an image IM3 by an interpolating image signal processing method. An optical sensor without fan-out configurations is used to sense an image IM4, which is processed into an image IM5. Comparing the image IM3 with the image IM5, it is found that the sensing area of the image IM3 is enlarged by about 30%.

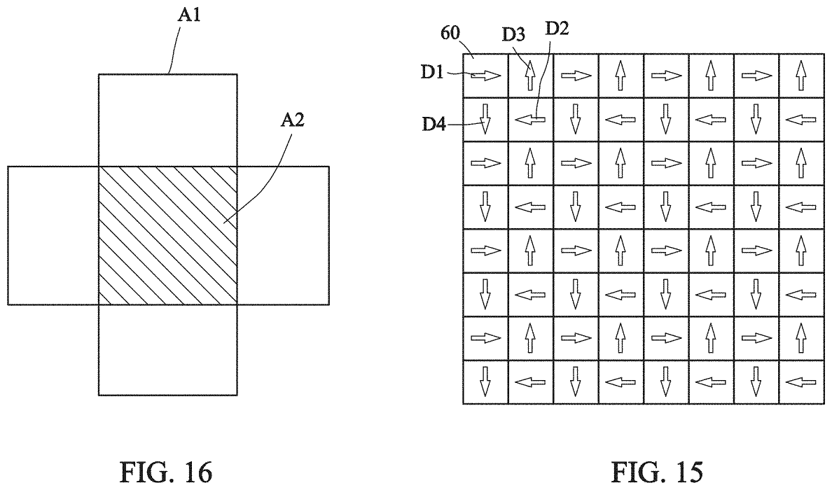

FIG. 15 is a schematic view showing another configuration of tilt directions of the oblique light of FIG. 11. FIG. 16 is a comparison diagram showing the area of the fingerprint image captured by the integrated optical sensor of FIG. 15. Referring to FIGS. 11, 15 and 16, a dual-axis fan-out configuration is provided. Adjacent four of the light receiving modules 60 respectively receive rightward; frontward; leftward and backward oblique light TL2, so that the image obtained by the light receiving modules 60 sensing the object F has a cruciform pattern. That is, the oblique light TL2 and the oblique light TL3 received by the adjacent four light receiving modules 60 have different tilt directions D1, D2, D3 and D4 with respect to the central optical axes OA2 of the micro lenses 40.

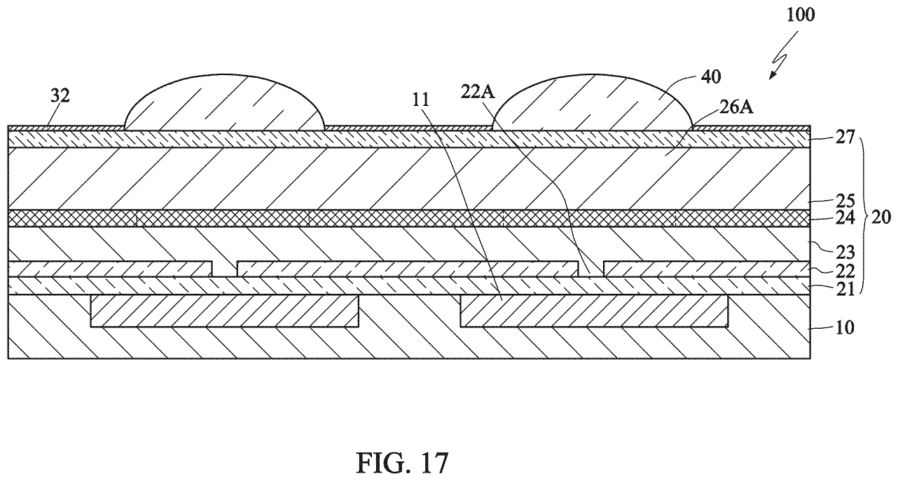

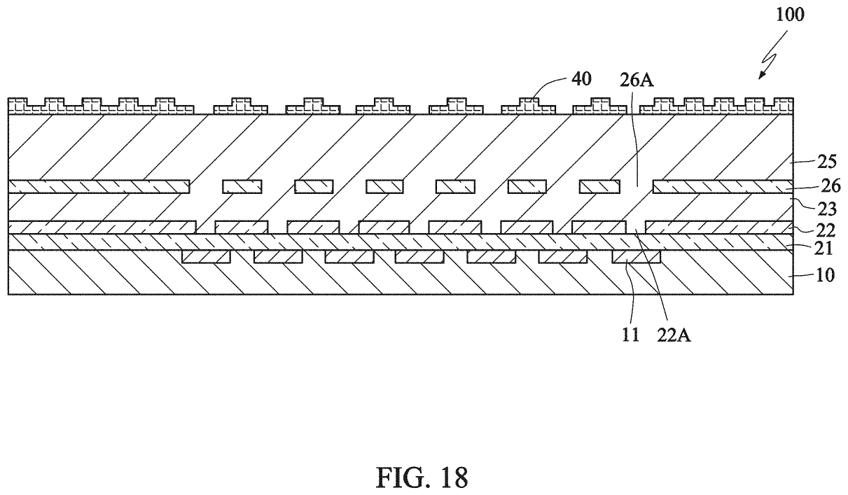

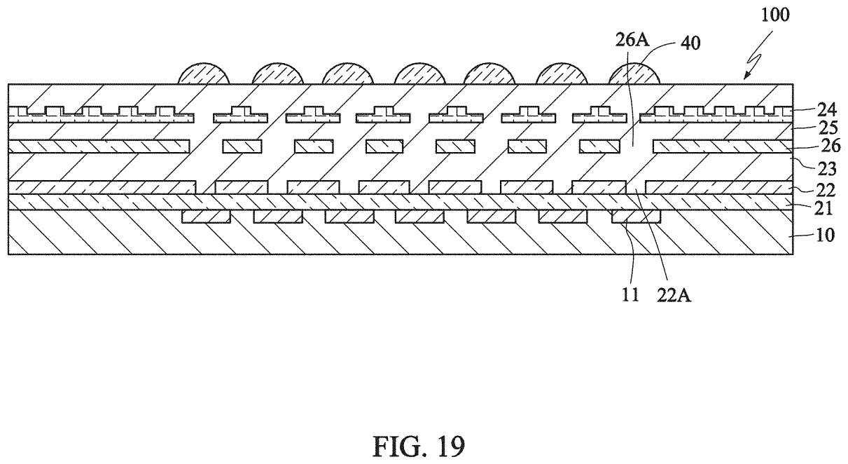

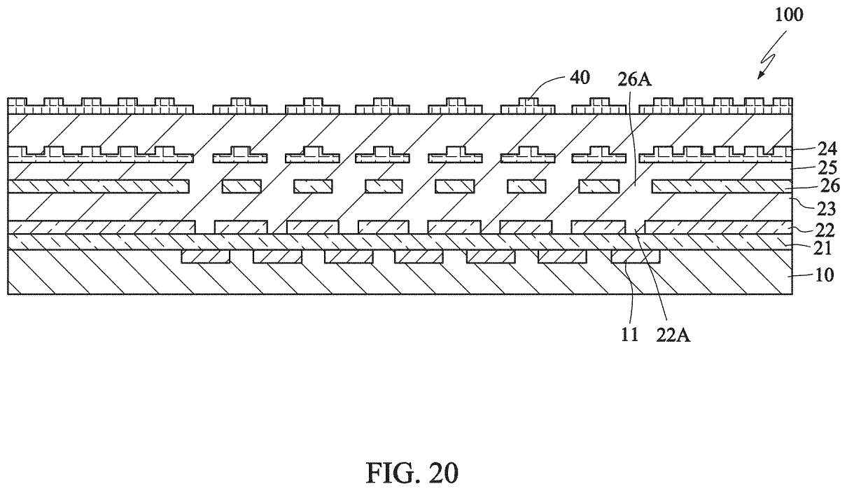

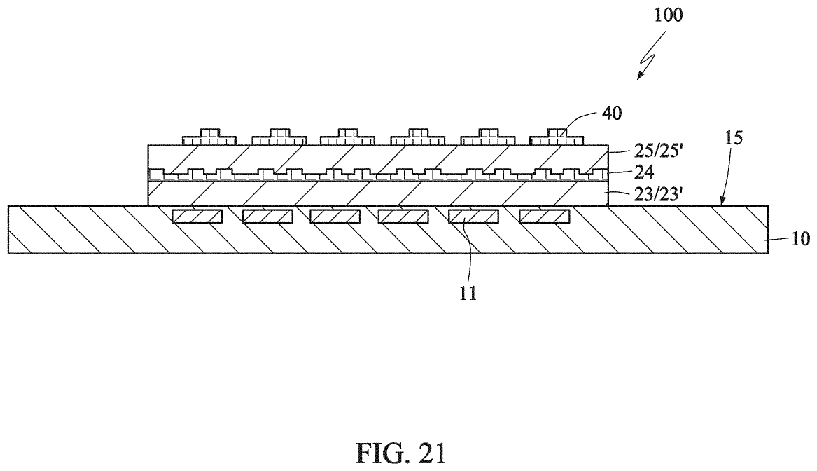

FIGS. 17 to 21 are schematic views showing modified examples of FIG. 1C. Referring to FIG. 17, the integrated optical sensor 100 further includes a stray light-absorbing layer 32, which is disposed on the optical module layer 20 and between the micro lenses 40, and absorbs stray light reflected in the optical module layer 20 to avoid the noise. The stray light-absorbing layer 32 is a carbon film layer in one example. Referring to FIG. 18, each micro lens 40 is a plasmonic focus lens. For example, the groove with two suhwavelength slits and special structures is designed to form the light focusing structure similar to the conventional lens. In nano-optics, the plasmonic lens generally refers to a lens for surface plasmon polariton (SPPs), and even to a device in which the SPPs are redirected to converge toward one single focal point. Because the SPPs may have the very short wavelength, they can be converged into the very small and very intense light spots much smaller than the free-space wavelength and the diffraction limit. It is worth noting that the second metal light shielding layer 26 can shield the oblique light. Referring to FIG. 19, the filter structure layer 24 is a plasmonic filter layer, which may be at least one metal layer or a composite structure having at least one metal layer collocating with at least one dielectric layer. The plasmonic filter structure can filter the infrared light or visible light, is disposed above the second metal light shielding layer 26 and under the micro lenses 40 or disposed between the micro lenses 40 and the first metal light shielding layer 22 (second metal light shielding layer 26), and performs filtering processing on the object light. Referring to FIG. 20, the plasmonic focus lenses and the plasmonic filter layer are integrated together to achieve the filtering and focusing effects. Referring to FIG. 21, the substrate 10 is a glass substrate, so that the above-mentioned design concept can be synchronously applied to an optical image sensor formed using the thin-film transistor (TFT) process. Upon manufacturing, a plasmonic filter layer 24 and plasmonic micro lenses 40 (on a spacer layer 25′) may be firstly formed on a glass substrate (or support substrate 23′), and then adhered or bonded to a TFT sensor 15 including the substrate 10 and the sensing pixels 11 by way of assembling and aligned with the sensing pixels 11 to provide the light focusing, collimating and filtering effects. Of course, the plasmonic micro lenses 40 and the plasmonic filter layer 24 may also be integrated on the TFT sensor using the TFT process to achieve the effects of this disclosure. Therefore, the optical sensor of this example includes the TFT sensor 15, the support substrate 23′/dielectric layer 23, the plasmonic filter layer 24, the spacer layer 25′/dielectric layer 25 and the plasmonic micro lenses 40. The support substrate 23′/dielectric layer 23 may be directly or indirectly (through an adhesive) disposed on the TFT sensor 15. The plasmonic filter layer 24 is disposed on the support substrate 23′/dielectric layer 23. The spacer layer 257 dielectric layer 25 is disposed on the plasmonic filter layer 24. The plasmonic micro lenses 40 are disposed on the spacer layer 25′/dielectric layer 25. The object light can reach the sensing pixels 11 of the substrate 10 (glass substrate) of the TFT sensor 15 through the plasmonic micro lenses 40, the spacer layer 25′/dielectric layer 25, the plasmonic filter layer 24 and the support substrate 23′/dielectric layer 23.

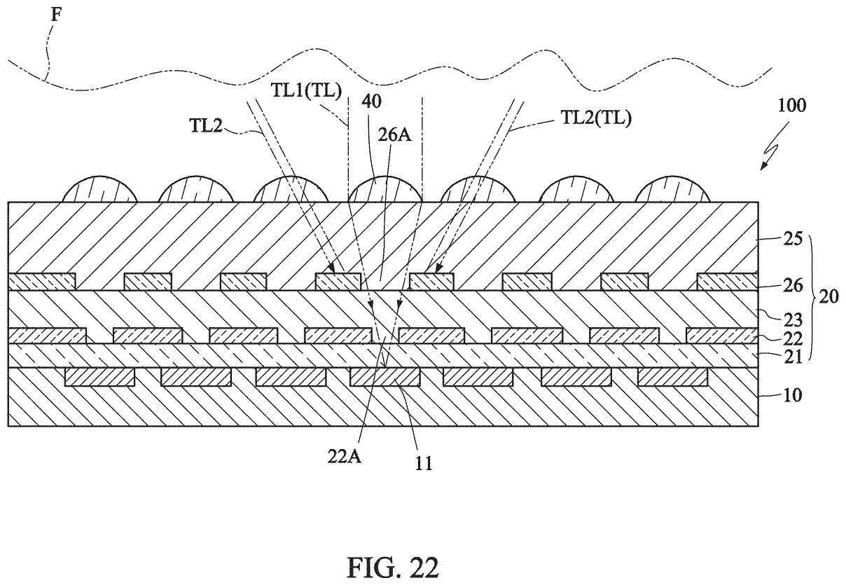

Referring to FIG. 22, this example is similar to FIG. 8 except for the difference that the micro lens 40 has the structure of FIG. 17. In FIG. 22, the optical path is further depicted to provide the further explanation. The integrated optical sensor 100 includes the substrate 10, the optical module layer 20 and the micro lenses 40. The substrate 10 is a semiconductor substrate having sensing pixels 11. The optical module layer 20 is disposed on the substrate 10. The micro lenses 40 are disposed on the optical module layer 20 having a thickness defining the focal length of the micro lenses 40. The sensing pixels 11 sense the object light TL, which is focused by the micro lenses 40 and optically processed by the optical module layer 20. The optical module layer 20 includes the first metal light shielding layer 22 and the first inter-metal dielectric layer 23 disposed above the first metal light shielding layer 22. The object light TL reaches the sensing pixels 11 through the first apertures 22A of the first metal light shielding layer 22. Thus, the metal layer used in the semiconductor process may also be adopted to achieve the light-obstructing effect.

In addition, the optical module layer 20 may further include a second metal light shielding layer 26 and a second inter-metal dielectric layer 25. The micro lenses 40 are disposed on the second inter-metal dielectric layer 25. The normal light TL1 of the object light TL reaches the sensing pixels 11 through multiple second apertures 26A of the second metal light shielding layer 26 and the first apertures 22A. The oblique light TL2 of the object light TL, which is also referred to as adjacent-lens oblique light passing through gaps between adjacent micro lenses, and is shielded by the second metal light shielding layer 26 from reaching the first inter-metal dielectric layer 23 and the sensing pixels 11.

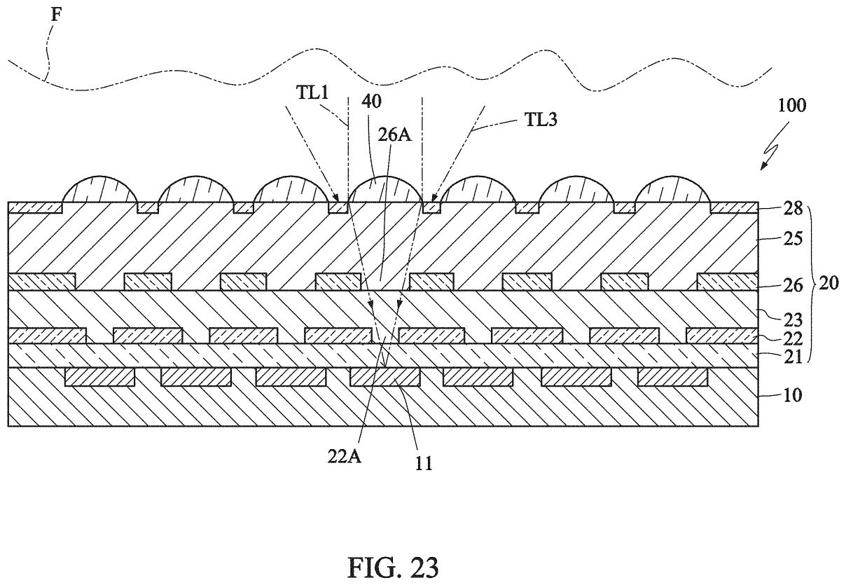

FIG. 23 is similar to FIG. 22 except for the difference that the optical module layer 20 further includes a third metal light shielding layer 28, which is disposed above the second metal light shielding layer 26 and between the adjacent micro lenses 40, and shields lens-gap oblique light TL3 of the object light TL (reaching gaps between adjacent micro lenses) from reaching the second inter-metal dielectric layer 25 to reduce the noise.

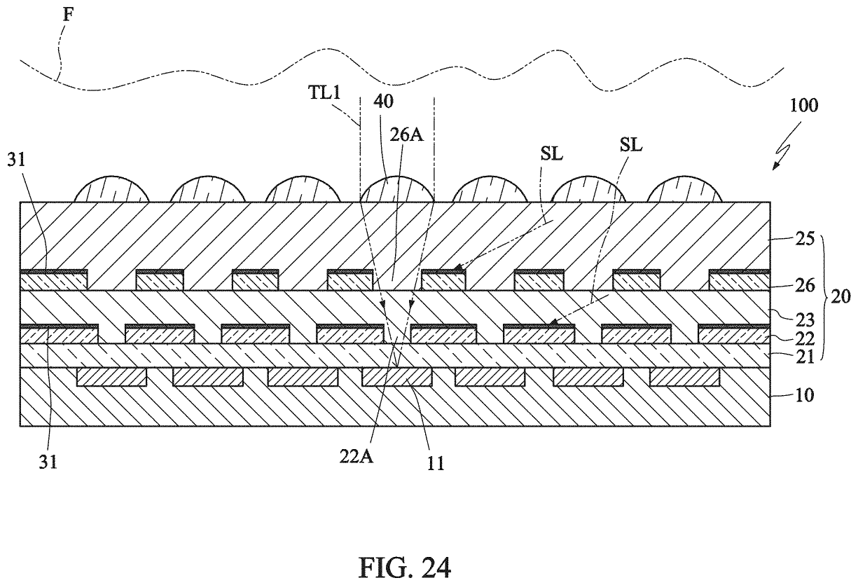

FIG. 24 is similar to FIG. 22 except for the difference that the optical module layer 20 further includes an anti-reflective layer 31, which is disposed on one or both of the second metal light shielding layer 26 and the first metal light shielding layer 22, and absorbs reflected stray light SL, travelling in the first inter-metal dielectric layer 23 and/or the second inter-metal dielectric layer 25, to reduce the noise.

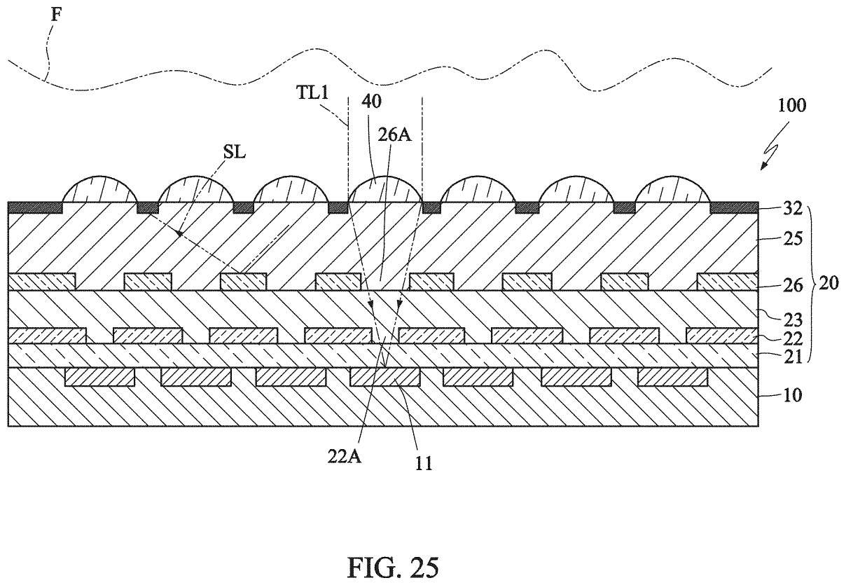

FIG. 25 is similar to FIG. 22 except for the difference that the optical module layer 20 further includes a stray light-absorbing layer 32, which is disposed above the second metal light shielding layer 26 and between adjacent ones of the micro lenses 40, and absorbs the stray light SL travelling in the second inter-metal dielectric layer 25,

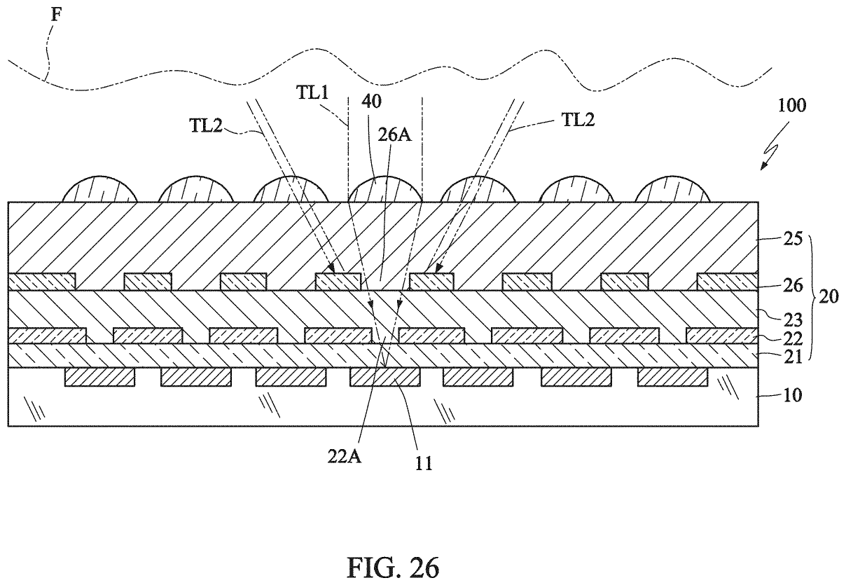

FIG. 26 is similar to FIG. 22 except for the difference that the substrate 10 is a glass substrate, on which the sensing pixels 11 are formed. It is worth noting that all the above-mentioned embodiments may be applied to the image sensor formed by the TFT process.

With the above-mentioned integrated optical sensor, the sensing pixels, the optical module layer and the micro lenses can be formed while active or passive devices are formed in the semiconductor process, and bonding pads and electrical connection structures of interconnection wires may also be formed at the same tune. Using the optical module layer to precisely control the imaging focal length of the micro lenses can achieve the effects of enhancing the process precision and decreasing the manufacturing cost. In addition, the optical sensor is applicable to both a semiconductor sensor and a TFT sensor.

The specific embodiments proposed in the detailed description of this disclosure are only used to facilitate the description of the technical contents of this disclosure, and do not narrowly limit this disclosure to the above-mentioned embodiments. Various changes of implementations made without departing from the spirit of this disclosure and the scope of the claims are deemed as falling within the following claims.

1. An integrated optical sensor, comprising:
a substrate having multiple sensing pixels;
an optical module layer disposed on the substrate; and
multiple micro lenses disposed on the optical module layer, wherein a thickness of the optical module layer defines a focal length of the micro lenses, the sensing pixels sense object light of an object, which is focused by the micro lenses and optically processed by the optical module layer, the optical module layer comprises a first metal light shielding layer and a first inter-metal dielectric layer disposed above the first metal light shielding layer, and the object light reaches the sensing pixels through multiple first apertures of the first metal light shielding layer.

2. The integrated optical sensor according to claim 1, wherein the substrate is a semiconductor substrate.

3. The integrated optical sensor according to claim 1, wherein the optical module layer further comprises a second metal light shielding layer and a second inter-metal dielectric layer disposed above the second metal light shielding layer, the micro lenses are disposed on the second inter-metal dielectric layer, normal light of the object light reaches the sensing pixels through multiple second apertures of the second metal light shielding layer and the first apertures, and adjacent-lens oblique light of the object light is shielded by the second metal light shielding layer and cannot reach the first inter-metal dielectric layer and the sensing pixels.

4. The integrated optical sensor according to claim 3, wherein the optical module layer further comprises a third metal light shielding layer disposed above the second metal light shielding layer and between adjacent two of the micro lenses, and the third metal light shielding layer shields lens-gap oblique light of the object light from reaching the second inter-metal dielectric layer.

5. The integrated optical sensor according to claim 3, wherein the optical module layer further comprises an anti-reflective layer, which is disposed on one or two of the second metal light shielding layer and the first metal light shielding layer, and absorbs reflected stray light.

6. The integrated optical sensor according to claim 3, wherein the optical module layer further comprises a stray light-absorbing layer, which is disposed above the second metal light shielding layer and between adjacent two of the micro lenses and absorbs stray light travelling in the second inter-metal dielectric layer.

7. The integrated optical sensor according to claim 3, further comprising a filter structure layer, which is disposed between the micro lenses and the second metal light shielding layer, and filters the object light.

8. The integrated optical sensor according to claim 1, wherein the substrate is a glass substrate.

9. The integrated optical sensor according to claim 1, wherein each of the micro lenses is a plasmonic focus lens.

10. The integrated optical sensor according to claim 1, further comprising a filter structure layer, which is disposed between the first metal light shielding layer and the micro lenses and filters the object light.

11. The integrated optical sensor according to claim 10, wherein the filter structure layer is a plasmonic filter layer.

12. The integrated optical sensor according to claim 11, wherein each of the micro lenses is a plasmonic focus lens.

13. A method of manufacturing an integrated optical sensor, the method comprising steps of:
using a semiconductor process to form multiple sensing pixels on a substrate;
forming an optical module layer on the substrate and the sensing pixels in the semiconductor process; and
forming multiple micro lenses on the optical module layer in the semiconductor process, wherein a thickness of the optical module layer defines a focal length of the micro lenses, the sensing pixels sense object light of an object, which is focused by the micro lenses and optically processed by the optical module layer, the optical module layer comprises a first metal light shielding layer and a first inter-metal dielectric layer disposed above the first metal light shielding layer, and the object light reaches the sensing pixels through multiple first apertures of the first metal light shielding layer.

14. The method according to claim 13, wherein the micro lenses are formed using a silicon dioxide material or a polymeric material in conjunction with a grayscale mask and etching.

15. The method according to claim 13, wherein the optical module layer further comprises a second metal light shielding layer and a second inter-metal dielectric layer disposed above the second metal light shielding layer, the micro lenses are disposed on the second inter-metal dielectric layer, normal light of the object light reaches the sensing pixels through multiple second apertures of the second metal light shielding layer and the first apertures, and adjacent-lens oblique light of the object light is shielded by the second metal light shielding layer and cannot reach the first inter-metal dielectric layer and the sensing pixels.
